(19) United States
(12) Patent Application Publication
(10) Pub. No.: US 2013/0105736 A1
(43) Pub. Date: May 2, 2013

(54) CONVERTER MATERIAL FOR SOLAR CELLS

(71) Applicants: Cornelis Reinder Ronda, Aachen (DE); Dirk Kornelis Gerhardus De Boer, Den Bosch (NL); Andries Meijerink, Soesterberg (NL); Nikolaos Christogiannis, Sheffield (GB); Danielle Beelen, Nederweert (NL); Wilhelmus Cornelis Keur, Weert (NL)

(72) Inventors: Cornelis Reinder Ronda, Aachen (DE); Dirk Kornelis Gerhardus De Boer, Den Bosch (NL); Andries Meijerink, Soesterberg (NL); Nikolaos Christogiannis, Sheffield (GB); Danielle Beelen, Nederweert (NL); Wilhelmus Cornelis Keur, Weert (NL)

(73) Assignee: KONINKLIJKE PHILIPS ELECTRONICS N.V., EINDHOVEN (NL)

(21) Appl. No.: 13/809,227

(22) PCT Filed: Jul. 5, 2011
(86) PCT No.: PCT/IB11/52972

§ 371 Date: Jan. 9, 2013

(30) Foreign Application Priority Data
Jul. 13, 2010 (EP) 10169389.3

(51) Int. Cl. H01L 31/0232

(52) U.S. Cl. CPC H01L 31/02322; Y10S 977/773; B82Y 30/00
USPC 252/301.4 R; 977/773

(57) ABSTRACT

The invention relates to an converter material for solar cells using Sm²⁺.

### FIELD OF THE INVENTION

The present invention is directed to converter materials for solar cells

### BACKGROUND OF THE INVENTION

State of the art solar cells cannot achieve the theoretical efficiency (as determined by the so-called “Shockley-Queisser” limit) for various reasons. Therefore many attempts have been made to increase the efficiency of Solar cells by either varying the solar cell material or addition of further components etc. Alternatively, the cost of solar cells can be reduced by the use of solar energy concentrators. Both measures have the potential to increase the use of solar cells as the costs per Wp decrease.

One strategy for the increase of solar cells is the introduction of converter materials which (most desirably) have a broadband absorption and line emission in desired wavelength areas. However there are not many converter materials known and therefore there is the constant need for alternative converter materials. These materials are used in so-called luminescent solar energy concentrators (LSC). Sunlight impinges on a large area, is converted into light of longer wavelenght and subsequently guided to photovoltaic elements. In this way the amount of expensive photovoltaic material to be used can be reduced considerably.

### SUMMARY OF THE INVENTION

It is an object of the present invention to provide a converter material for solar cells which is able to decrease the costs and to increase efficiency for the conversion of deep blue/UV radiation of solar cells by a broadband absorption and line emission in suitable wavelength areas.

This object is solved by a converter material for solar cells according to claim 1 of the present invention. Accordingly, an converter material for solar cells, is provided, comprising a Sm²⁺ doped inorganic material

Surprisingly it has been found that such a converter material for solar cells has for a wide range of applications within the present invention at least one of the following advantages:
The materials comprising Sm²⁺ employ for many applications a large Stokes shift,
The efficiency is increased as the conversion efficiency of solar cells is decreasing rapidly below 400 nm.
The costs of solar cells are decreased when the inventive materials are used in solar cells, such as LSCs.
Furthermore many inventive materials show a broad tunable absorption spectrum
In most inventive materials line emission can be observed which prevents reabsorption (forbidden transitions)
Furthermore it has been found that said line emission is (almost) independent of the host lattice, enabling the use of more than one luminescent material (to absorb as much sunlight as possible) in combination with interference filters, to keep the emission within the solar cell

Preferably the converter material for solar cells the converter material for solar cells is selected from the group comprising oxidic, nitridic, oxidonitridic, boridic, borate, phosphate materials and mixtures thereof. These materials have been found advantageous in practice. Additionally or alternatively according to another embodiment of the present invention, the the converter material is selected from the group comprising alkaline and/or earth alkaline containing materials.

According to a preferred embodiment of the present invention, the converter material has a band gap of ≧4.5 eV. This has been advantageous for many applications since then it has been found that in materials with too small a value for the bandgap, the excited Sm²⁺ ions easily oxidise to Sm³⁺ and this results in quenching of the emission. Preferably the converter material has a band gap of ≧5 eV.

According to a preferred embodiment, the undoped material is a non-coloured material which is coloured when doped with Sm²⁺.

The term “non-coloured” especially means and/or includes that the material has no absorption in the visible wavelength area or an absorption of ≦10%, whereas the term “coloured” to the contrary especially means and/or includes that the material has an absorption and/or emission (preferably of larger than 50%) in the visible wavelength area.

According to a preferred embodiment, the converter material comprises an earth-alkaline borate, preferably a material of the structure EA₁₋ₓB₄O₇:Smₓ with EA being an earth alkaline metal or mixtures of earth alkaline metals. Preferably EA is Sr and/or Ba.

This material has shown in practice to be a very good converter material as will be described later on.

The present invention furthermore relates to the use of Sm²⁺ as absorber and/or emitter in converter materials for solar cells

Furthermore the present invention relates to a solar cell using an inventive material or making use of Sm²⁺ as absorber and/or emitter in converter materials for solar cells.

Preferably the converter material is provided in said solar cells in nanoparticle form, preferably with an average particle size of ≧1 nm and ≦1 μm, preferably ≧100 nm and ≦500 nm, most preferred ≧50 nm and ≦100 nm. This is especially advantageous when the converter is present in a light guide, as scattering losses are reduced in this way, provided that the refractive indices (n) of the light guide and the phosphor materials match (typically Δn<0.05).

Alternatively the the converter material is provided in said solar cells in form of grains with with an average particle size of ≧1 μm, more preferred ≧5 μm. This arrangement is especially advantageous when the converting layer is positioned under the light guide with respect to the direction of the light.

The aforementioned components, as well as the claimed components and the components to be used in accordance with the invention in the described embodiments, are not subject to any special exceptions with respect to their size, shape, material selection and technical concept such that the selection criteria known in the pertinent field can be applied without limitations.

### BRIEF DESCRIPTION OF THE DRAWINGS

Additional details, features, characteristics and advantages of the object of the invention are disclosed in the subclaims, the figures and the following description of the respective figures and examples, which—in an exemplary fashion—show several embodiments and examples of converter material for solar cellss according to the invention.

FIG. 1 shows an emission spectrum of an inventive material according to the present invention (Example I)

FIG. 2 shows the excitation spectrum of the material of FIG. 1

The invention will furthermore be understood by the following Inventive Example which is merely for illustration of the invention only and non- limiting.

### EXAMPLE I

Example I refers to SrB₄O₇:Sm²⁺ which was made the following way:

Stoichiometrically mixtures of Sm₂O₃, SrCO₃, H₃BO₃ (10% excess) were fired at 850° C. for 20 hours in a reducing atmosphere (H₂/N₂). The samples were checked by x-ray diffraction technique and their phase purity was confirmed.

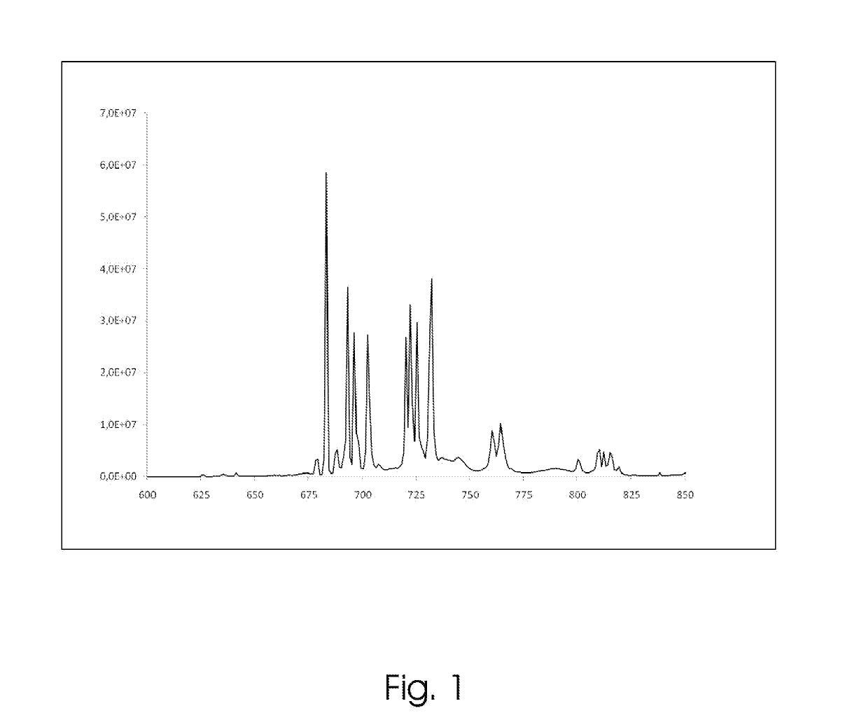

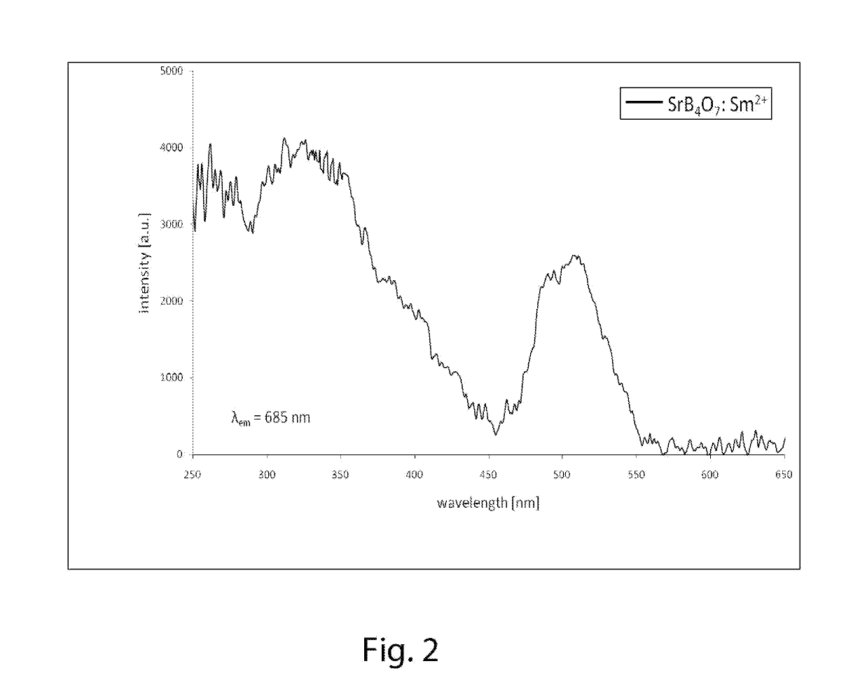

FIG. 1 shows the emission spectrum, FIG. 2 shows the excitation spectrum of SrB₄O₇:Sm²⁺. It can clearly be seen that this material is an excellent material of use in converter material for solar cells due to the broadband absorption of the material as well as the line emission together with a broad Stokes shift.

The particular combinations of elements and features in the above detailed embodiments are exemplary only; the interchanging and substitution of these teachings with other teachings in this and the patents/applications incorporated by reference are also expressly contemplated. As those skilled in the art will recognize, variations, modifications, and other implementations of what is described herein can occur to those of ordinary skill in the art without departing from the spirit and the scope of the invention as claimed. Accordingly, the foregoing description is by way of example only and is not intended as limiting. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage. The invention's scope is defined in the following claims and the equivalents thereto. Furthermore, reference signs used in the description and claims do not limit the scope of the invention as claimed.

1. Converter material for solar cells comprising a Sm²⁺ doped inorganic material, whereby the converter material has a band gap of ≧4.5 eV.

2. The converter material for solar cells of claim 1, whereby the converter material for solar cells is selected from the group comprising oxidic, nitridic, oxidonitridic, boridic, borate, phosphate materials and mixtures thereof

3. The converter material for solar cells of claim 1, whereby the converter material is selected from the group comprising alkaline and/or earth alkaline containing materials.

4. (canceled)

5. The converter material for solar cells of claim 1 whereby the emission of the converter material has a decay time of ≧50 μs.

6. The converter material for solar cells of claim 1, whereby the undoped material is a non-coloured material which is coloured when doped with Sm²⁺.

7. The converter material for solar cells of claim 1, whereby the converter material comprises an earth-alkaline borate.

8. (canceled)

9. Solar cell comprising a converter material according to claim 1.

10. Solar cell of claim 9, whereby the converter material is provided in the form of nanoparticles.
